(19) United States
(12) Patent Application Publication
(10) Pub. No.: US 2020/0073759 A1
(43) Pub. Date: Mar. 5, 2020

(54) MAXIMUM DATA RECOVERY OF SCALABLE PERSISTENT MEMORY

(71) Applicant: HEWLETT PACKARD ENTERPRISE DEVELOPMENT LP, Houston, TX (US)

(72) Inventors: Jason Spottswood, Houston, TX (US); Marvin Spinhirne, Mesquite, TX (US); Mark S. Fletcher, Houston, TX (US)

(21) Appl. No.: 16/122,490

(22) Filed: Sep. 5, 2018

(51) Int. Cl. G06F 11/14; G06F 11/10; G11C 29/10; G11C 29/44

(52) U.S. Cl. CPC G06F 11/1451; G06F 11/1441; G11C 29/44; G06F 11/106; G11C 29/10; G06F 11/1458

(57) ABSTRACT

A scalable persistent memory for a computing resource includes a scalable persistent memory region allocated in system memory of the computing resource. In case of system shutdowns, the contents of the scalable persistent memory region is transferred to a backup storage resource. Transfers to the backup storage resource occur in data blocks consisting of a plurality of data lines. A data block may be rejected by the backup storage resource if the data block is found to contain data errors. For any data block rejected by the backup storage resource during a data transfer, the rejected block is scanned in data line increments and scrubbed by replacing or overwriting any data line found to contain an error with error-free data. A scrubbed block is then stored in a known good region of system memory previously determined to be error-free. The previously rejected data block is then transferred from the known good region to the backup storage resource. Data recovery from the backup process is maximized through avoidance of entire data blocks being rejected.

### BACKGROUND

In computing systems, persistent and/or non-volatile memory resources are memory resources capable of retaining data even after system shutdowns, such as when power is removed due to unexpected power loss, system crash, or a normal shutdown. Non-volatile memory resources may utilize volatile memory components (e.g., DRAM) during normal operation, and transfer (“dump”) the contents of such volatile memory into backup memory, which may be non-volatile memory, in the event of a normal system shutdown, or even in the event of a power failure, such as by using a temporary backup power source.

The contents of volatile memory may be transferred to backup memory in increments of data blocks each consisting of a number of data lines. During the data block transfers, error correction mechanisms may be operable to identify errors in the data. In some cases, the backup memory will reject storage of a data block identified as containing an error; that is, an entire data block may be rejected, even if the error is determined to reside in only one data line within the data block. Subsequent data recovery from a shutdown may therefore be less complete.

### BRIEF DESCRIPTION OF THE DRAWINGS

For a detailed description of various examples, reference will now be made to the accompanying drawings, in which:

FIG. 1 is a block diagram of computing system incorporating a persistent memory in accordance with one example;

FIG. 2 is flow diagram representing operation of a computing system incorporating a persistent memory in accordance with one example;

FIG. 3 is a flow diagram representing operation of a computing system performing a scanning operation to identify a known good region of system memory;

FIGS. 4A and 4B together are a flow diagram representing operation of a computing system performing a transfer operation from a scalable persistent memory region to a backup memory resource;

FIG. 5 is a flow diagram representing operation of a computing system performing a restore operation for a scalable persistent memory region from a backup memory resource;

FIG. 6 is a block diagram representing a computing resource implementing a method of infrastructure program management, according to one or more disclosed examples;

FIG. 7 is a block diagram representing a computing resource implementing a method of infrastructure program management, according to one or more disclosed examples;

FIGS. 8A and 8B together comprise a block diagram representing a computing resource implementing a method of infrastructure program management, according to one or more disclosed examples; and

FIG. 9 illustrates a computer processing device that may be used to implement the functions, modules, processing platforms, execution platforms, communication devices, and other methods and processes of this disclosure.

### DETAILED DESCRIPTION

In this description, for purposes of explanation, numerous specific details are set forth in order to provide a thorough understanding of the examples disclosed herein. It will be apparent, however, to one skilled in the art that the disclosed example implementations may be practiced without these specific details. In other instances, structure and devices are shown in block diagram form in order to avoid obscuring the disclosed examples. Moreover, the language used in this disclosure has been principally selected for readability and instructional purposes and may not have been selected to delineate or circumscribe the inventive subject matter, resorting to the claims being necessary to determine such inventive subject matter. Reference in the specification to “one example” or to “an example” means that a particular feature, structure, or characteristic described in connection with the examples is included in at least one implementation.

The term “information technology” (IT) refers herein broadly to the field of computers of all types, computing systems, and computing resources, the software executed by computers, as well the mechanisms, physical and logical by which such technology may be deployed for users.

The terms “computing system” and “computing resource” are generally intended to refer to at least one electronic computing device that includes, but is not limited to including, a single computer, virtual machine, virtual container, host, server, laptop, and/or mobile device, or to a plurality of electronic computing devices working together to perform the function(s) described as being performed on or by the computing system. The term also may be used to refer to a number of such electronic computing devices in electronic communication with one another.

The term “cloud,” as in “cloud computing” or “cloud resource,” refers to a paradigm that enables ubiquitous access to shared pools of configurable computing resources and higher-level services that can be rapidly provisioned with minimal management effort; often cloud resources are accessed via the Internet. An advantage of cloud computing and cloud resources is that a group of networked computing resources providing services need not be individually addressed or managed by users; instead, an entire provider-managed combination or suite of hardware and software can be thought of as an amorphous “cloud.”

The term “non-transitory storage medium” refers to one or more non-transitory physical storage media that together store the contents described as being stored thereon. Examples may include non-volatile secondary storage, read-only memory (ROM), and/or random-access memory (RAM), Such media may be optical or, magnetic.

The terms “application” and “function” refer to one or more computing modules, programs, processes, workloads, threads and/or a set of computing instructions executed by a computing system. Example implementations of applications and functions include software modules, software objects, software instances and/or other types of executable code. Note, the use, of the term “application instance” when used in the context of cloud computing refers to an instance within the cloud infrastructure for executing applications (e.g., for a customer in that customer's isolated instance).

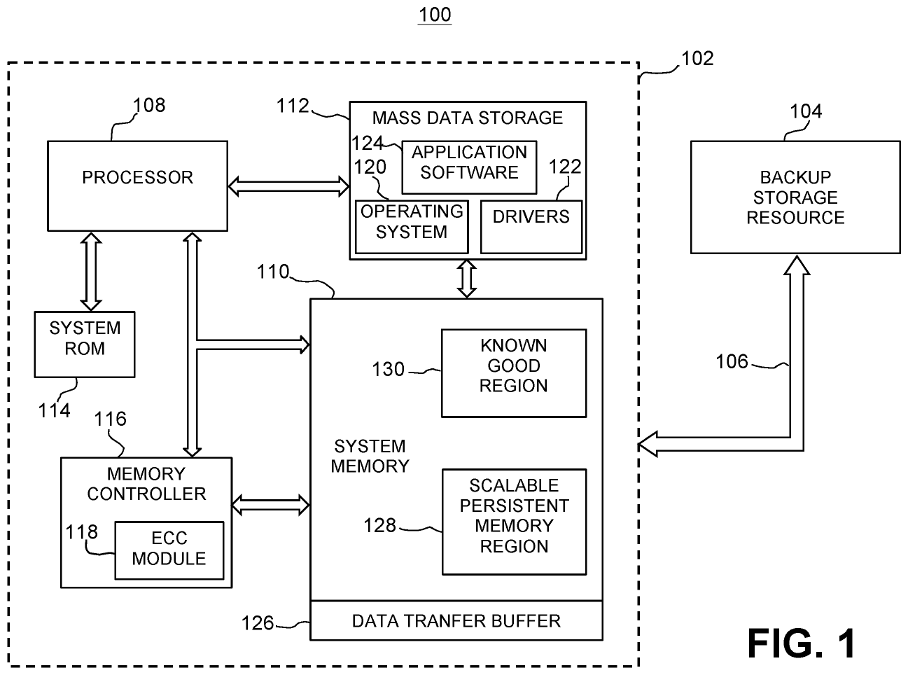

Referring to FIG. 1, there is shown a computing system 100 implementing a scalable persistent memory and including a computing resource 102 and a backup storage resource 104. In this example, computing resource 102 comprises a computer, such as a server, including a processor 108, such as a conventional central processing unit (CPU), system memory 110, such as volatile dynamic random access memory (DRAM), and a mass storage device 112, such as a magnetic or solid state hard disk drive (HDD).

Backup storage resource 104 may be implemented in various ways, including storage comprising NVDIMMs, solid-state disk drives, disk drive arrays (e.g., RAIDs), and so on, in any manner known to the art. The connection 106 shown in FIG. 1 between computing resource 102 and backup storage resource 104 may also be implemented in many ways, ranging from direct physical connections to computing resource 102 or some subcomponent thereof, network connections, Ethernet connections, Internet connections, and so on.

In a conventional arrangement, processor 108 operates in part by executing system programming, i.e., code, stored in system read-only memory (system ROM) 114. That is, operation of processor 108 may be controlled by causing processor 108 to execute code stored in system ROM 114. Memory controller 116 coordinates memory storage and retrieval functions between processor 108, system memory 110, mass data storage 112, and backup storage resource 104. Memory controller 116 may include an error correction code (ECC) module 118 operable to detect data errors as memory contents are transferred and stored in various system components, and in particular to detect data errors in data transferred between system memory 110 and backup storage resource 104.

Mass data storage 112 may store, among other things, operating system 120 for controlling overall operation of computing resource 102, as well as drivers 122 for facilitating cooperation of computing resource 102 with external devices and processes (not shown), such as printers, modems, external storage devices, and so on. Mass data storage 112 may also store application software 124 to be executed by processor 108.

Data stored in system memory 110 may be byte-addressable by processor 108; that is, processor 108 can access any selected byte of data within system memory 110 by specifying a byte address to memory controller 116. Data transfers between system memory 110 and backup storage resource 104, on the other hand, are typically performed in increments consisting of data blocks, i.e., multiple bytes spanning a range of byte addresses. Each data block, in turn, may consist of multiple data lines, i.e., multiple bytes spanning a subset of the byte address range of the data block.

For example, for byte-addressable system memory of arbitrary size, a data block may consist of 128k bytes, with each 128 Kb data block consisting of 2000 64-byte data lines. In one example, data transfers between system memory 110 and backup storage 104 occur via a data transfer buffer 126, which may store, for example, one or more 128 Kb data blocks at a time. ECC module 118 may operate to detect data errors in data blocks as they are loaded into data buffer 126 to be transferred to backup storage resource 104. As noted, such errors can occur for various reasons, including permanently or transiently corrupted memory locations in system memory (e.g., DRAM) 110.

When ECC module 118 detects a data block in buffer 126 which contains a data error, the data block is “flagged,” i.e., identified as containing an error. A data block flagged as containing a data error will under most circumstances be rejected by backup storage resource 104 during the process of transferring some or all of the contents of system memory 110 to backup storage resource 104.

Although FIG. 1 depicts computing resource 102 as a combination of individual functional components, such as processor 108, system memory 110, mass data storage 112, etc., it is to be understood that individual functional elements may be scalable and distributed in various ways for example in accordance with known networking, clustering, and distributed computing methodologies. For example, the processing capabilities represented by processor 108 in FIG. 1 may be implemented as a “virtual” machine comprising multiple independent processors operated cooperatively. Similarly, storage capabilities of mass data storage 112 may be implemented using multiple interconnected storage units (not shown). The connections and connectivity between the various functional elements of the computing system 100 of FIG. 1 may include hardware connections, local area network connections, wide area network connections, Internet (e.g., “cloud”) connections, and so on.

In one implementation, a region (e.g., an address range) of system memory 110 may be designated, for example, through execution of operating system 120 or application software 124 by processor 108, as a scalable persistent memory region 128. Such a region is intended to function essentially as a virtual non-volatile dual in-line memory module (virtual NVDIMM), such that data stored in scalable persistent memory region 128 is preserved in case of system shut-downs, including either un-planned power interruptions or intentional shut-downs.

Conventional NVDIMMs, such as those of the NVDIMM-N variety, may include flash (i.e., non-volatile) storage and traditional DRAM on the same physical module, which is interfaced with the memory bus of a computer. A computing system accesses the traditional DRAM of the NVDIMM directly. In the event of a power failure, an NVDIMM module copies data from volatile traditional DRAM to persistent (e.g., flash) storage, and copies it back when power is restored. An NVDIMM may use a backup power source such as a battery or supercapacitor to facilitate data transfer from volatile to backup memory in the event of unplanned power failures.

Whereas conventional NVDIMMs consist of separate self-contained hardware modules interfaced to a computer system's memory bus, a “virtual” NVDIMM as described herein may be implemented by providing a scalable persistent memory region 128 in system memory 110, as herein described. Scalable persistent memory region 128 may be presented to the operating system 120 using an industry-standard defined NVDIMM interface, such that the operating system 120 can access it in the same manner it would a physical NVDIMM device.

To implement a scalable persistent memory region 128 in system memory 110 that is operable as a “virtual” NVDIMM, the contents of that region 128 are transferred to backup storage resource 104 at various times. As described above, such transfers typically occur either prior to planned power outages which would cause the contents of volatile memory to be lost, or unplanned power outages, in which the contents of volatile memory are lost unless backup power is provided to system memory at least temporarily.

In the example of FIG. 1, whenever data is to be transferred from scalable persistent memory region 128 to backup storage resource 104, memory controller 116 will accomplish the transfer in data-block increments, each data block first typically being transferred/copied to data buffer 126 and then transferred/copied to backup storage resource 104. During such transfers, ECC module 118 may detect a data error in a buffered data block using conventional ECC methodologies, and will then flag the data block accordingly. In some cases, such an error flag will cause backup storage resource 104 to reject the data block. Such rejection of flagged data blocks occurs automatically even if only a small fraction of a transferred data block is determined to have errors. The rejection of a data block by backup storage resource 104 undesirably leads to the omission of an entire data block from the transferred data, whereas the data error is likely to be limited to a much smaller memory range, for example, a single data line within the data block.

To address this undesirable outcome, according to one approach a provision is made for identifying a “known good” region 130 of system memory 110. In one implementation, such a known good region 130 may include an address range of one or more data blocks in size.

In one example, a known good region 130 is identified by processor 108, executing instructions stored in system ROM 114 causing processor 108 to perform a “scrubbing” or “scanning” operation on system memory 110. Under control of instructions stored in system ROM 114, processor 108 has byte-addressable access to system memory 110, and can perform such a scanning or scrubbing operation by reading each byte in an allocated data block range of memory addresses. If an ECC error occurs during this scanning/scrubbing process, the read operation will trigger failure from the processor 108, and that failure will be handled by memory error handler routines in system ROM 114.

Once an allocated memory space of a data block (or greater) in size is scanned or scrubbed and found to be without FCC errors, that memory space may be designated as known good region 130 to be used as a recovery transfer buffer as herein described.

During a backup operation in which the contents of scalable persistent memory region 128 are to be transferred to backup storage resource 104, a log of all failed (i.e., rejected) data block transfers may be maintained. Once all data blocks not found to have contained errors have been transferred, the data blocks from failed transfers may be separately scanned or scrubbed by processor 108, on a byte-accessible basis and under control of system ROM 114. For each data line read from a data block that does not result in an FCC error, the data is copied to known good region 130. When an ECC error in a data block is encountered during the CPU scan, the memory error interrupt handler code in system ROM 114 will prevent system crashing by clearing the error status and returning execution back to the CPU to continue the scan operation. Using output parameters from the system ROM 114 error interrupt handler, a scan operation can avoid copying the error to known good region 130, instead storing NULL data at the error location(s) in the buffer.

Once known good region 130 is full, its contents can then be sent to backup storage resource 104 for backup. All errors found during the read scan operation may be recorded in order, for example, to inform operating system 120 to avoid the memory address ranges associated with the detected errors. In this way, the amount of data lost during backup to backup storage resource 104 is advantageously reduced from an entire data block (e.g., 128 Kb) to only one data line (e.g., 64 bytes), or at most multiple data lines comprising less than an entire data block.

Advantageously, the size of scalable persistent memory region 128 can be of any arbitrary memory capacity, in contrast to conventional NVDIMMs, for example, wherein memory capacity is necessarily determined by the physical hardware provided. Particularly when it is considered that a computing resource such as computing resource 102 may in turn be implemented as a combination of physical hardware elements (processing, memory, and so on) and/or possibly combinations of such discrete hardware elements combined via networking, cloud computing, and other combinatorial methods to function as “virtual” hardware elements, a theoretically limitless degree of scalability may be achieved.

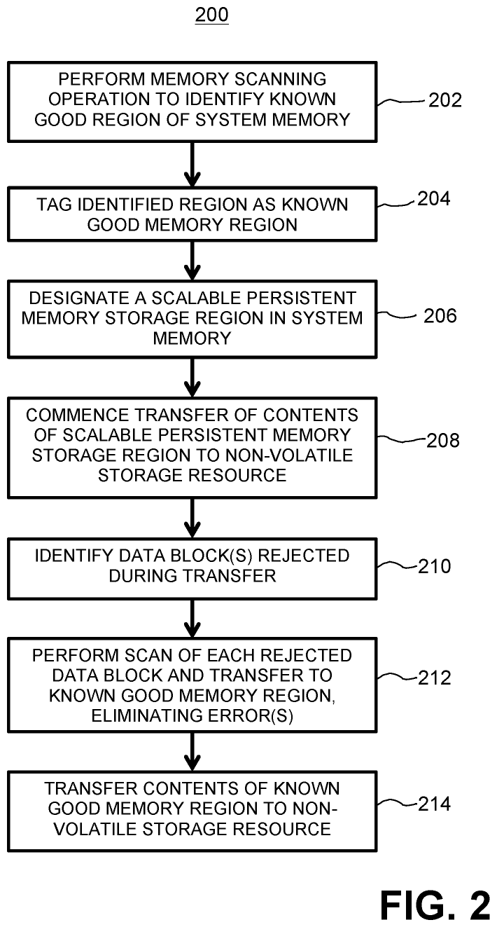

FIG. 2 is a flow diagram 200 representing operation of a scalable persistent memory system including operational elements such as depicted in the example of FIG. 1. In FIG. 2, a first step in ensuring the recoverability of the maximum amount of data from a scalable persistent memory as described herein is to perform a scanning function to identify and allocate a “clean” or “known good” region of system memory 110 sufficient to accommodate at least one data block, e.g., a 128 Kb region. This is represented by block 202 in FIG. 2. As noted, this scanning function is performed by processor 108, which has byte-addressable access to memory 110, and may occur during a system ROM boot of computing resource 102.

During normal operation of computing resource 102, such as under control of operating system 120, an ECC error can cause a system crash. However, if processor 108 performs the scanning operation corresponding to block 202 in the context of a system ROM boot and under control of system ROM 114, an encountered ECC error can be ignored and used as a signal to avoid using the offending memory location or range. The memory error interrupt handler of system ROM 114 can accomplish this by clearing the error status and returning execution back to the ROM boot process.

Once a region of system memory 110 of sufficient size (e.g., one 128 kB data block) is identified as being error-free, that region is tagged as known good region 130, as represented by block 204 in FIG. 2.

During operation, software executed by processor 108 may cause a portion of system memory 110 to be designated as a scalable persistent memory region 128, i.e., essentially a virtual NVDIMM. This is represented by block 206 in FIG. 2.

When during operation of computing resource 102, it becomes necessary to transfer the contents of scalable persistent memory region 128 to backup storage resource 104, such as for a system shut-down, the transfer operation commenced on a data-block by data-block basis, with successive data blocks being written to data transfer buffer 126 and then transferred to backup storage resource 104 via connection 106. This is represented by block 208 in FIG. 2.

During these data block transfers of block 208, any data block determined by ECC module 118 to contain an error will be rejected by backup storage resource 104. The address range of any rejected data block will be recorded, as represented by block 210 in FIG. 2.

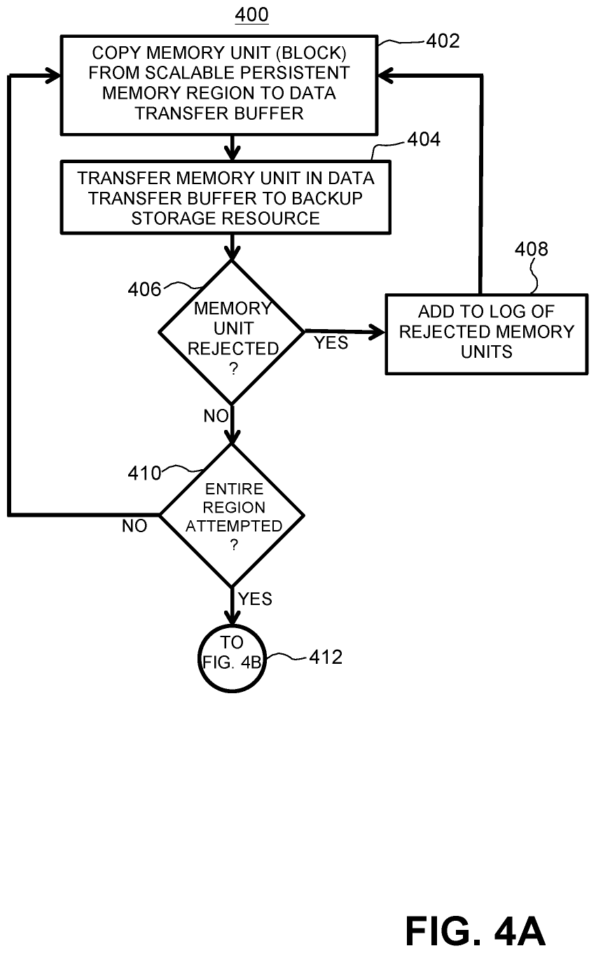

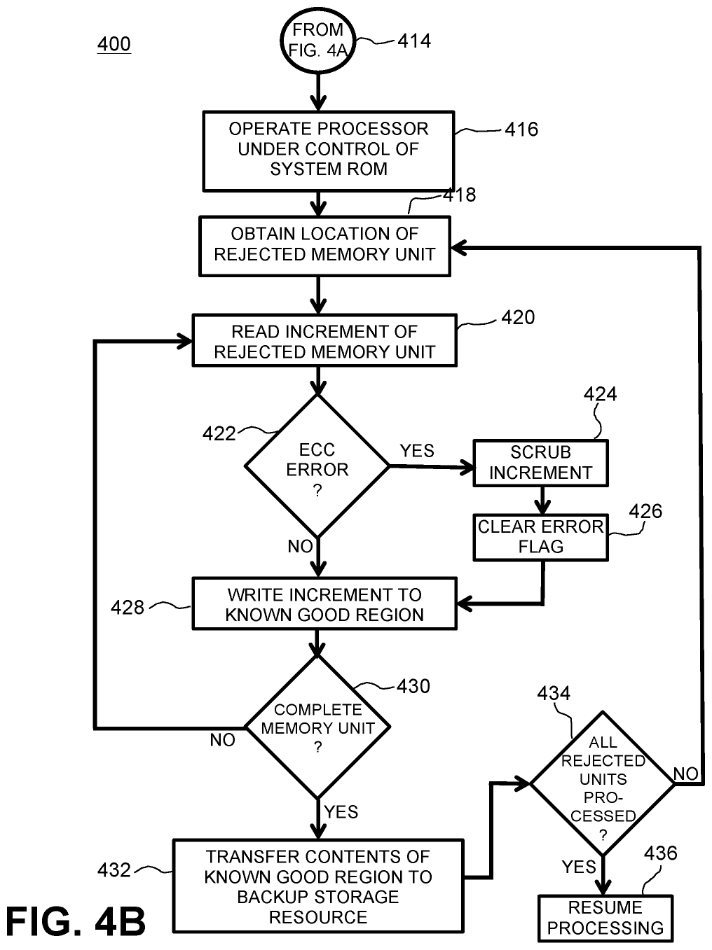

Next, in block 212, processor 108 under control of system ROM 114, performs a scan operation on each data block rejected in block 210 for containing ECC errors. This scan operation, described in further detail with reference to FIGS. 4A and 4B, may take place on an incremental basis, such as one data line (64 bytes) at a time for each increment in the data block. During this scan, processor 108 operates to “scrub” ECC errors out of the data block by overwriting data increments (e.g., data lines) exhibiting ECC errors with error-free data, which may consist, for example, of NULL data.

Once each line is scanned, and if necessary, scrubbed, it is written to known good region 130, as represented by block 212 in FIG. 2. When the entire data block has been written to known good region 130, a data transfer from known good region 130 to backup storage resource 104, as represented by block 214 in FIG. 2. Since the data causing ECC errors has been scrubbed, and since known good region 130 was previously found to contain no ECC-prone locations, this transfer at block 214 is not likely to be rejected. Desirably, however, only those data increments (e.g., data lines) which had to be scrubbed during the scan operation of block 212 will be omitted from the transfer, as opposed to the entire data block.

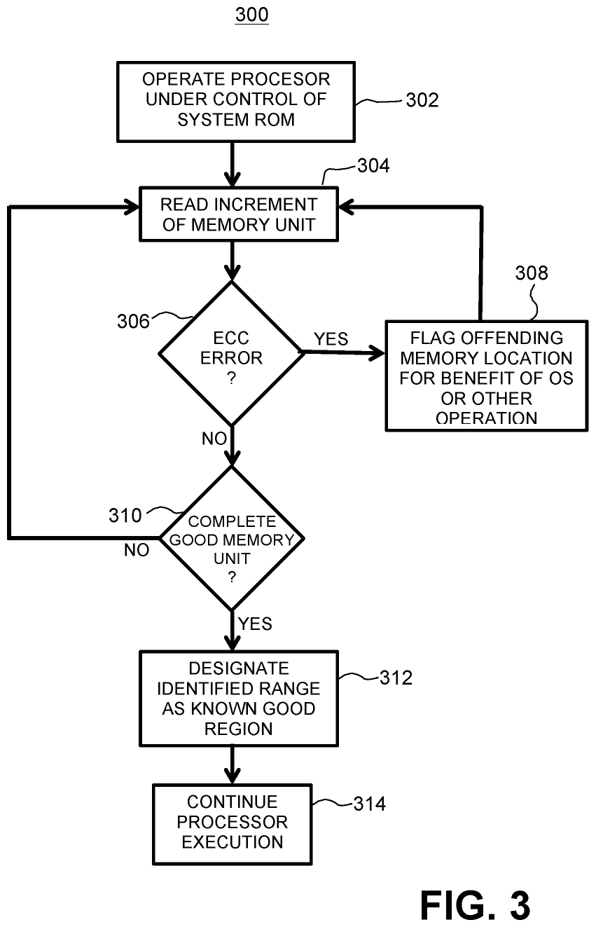

Turning to FIG. 3, there is shown a flow diagram 300 of a scan process for identifying/isolating known good region 130 in accordance with one example. Preferably, and as represented by block 302 in FIG. 3, the scan operation of FIG. 3 is performed by CPU under control of system ROM 114, such that the memory error handler in system ROM 114 can handle any ECC errors encountered.

The scan operation involves reading increments, such as 64-byte data lines, of a larger memory unit in system memory, such as a 256 kB data block. This is represented by block 304 in FIG. 3. As each memory increment is read, the system ROM 114 ECC memory error handler determines whether the read caused an ECC error, as represented by decision block 306 in FIG. 3. If an ECC error occurred, in block 308 the offending memory location is flagged for the benefit of later operation, such as when CPU is operating under control of operating system 120.

If a given read does not give rise to an ECC error, then at decision block 310 a determination is made whether sufficient memory increments have been read to create a known good region 130 of the desired size, e.g., one data block. If not, the process continues with a return to block 304 for a further memory increment read.

When sufficient memory has been scanned, at block 312 the memory range (which may or may not involve contiguous memory locations) is designed as known good region 130, and then CPU execution continues, at block 314.

FIGS. 4A and 4B together comprise a flow diagram 400 illustrating a process of “dumping” or transferring the contents of scalable persistent memory region 128 to backup storage resource 104, for example, in preparation or response to a system shutdown.

The transfer operation begins at block 402 in FIG. 4A with the copying of a memory unit, such as a data block, from scalable persistent memory region 128 to data transfer buffer 126. Thereafter, at block 404, the contents of data transfer buffer 126 are transferred to backup storage resource 104. During the memory transfer, data in data transfer buffer 126 will be acted upon by ECC module 118 and flagged in the event of an ECC error being detected. If a data unit (e.g., data block) is flagged with an ECC error, as represented by decision block 406 in FIG. 4A its transfer to backup storage resource 104 will be rejected. When a data unit is rejected, its identity is recorded in a log, as represented by block 408, and the next data unit is copied to data transfer buffer 126, in block 402.

When a data unit is not rejected, next a determination is made whether all of the data units in the scalable persistent memory region 128 have been attempted, in decision block 410. If not, another data block is copied into data transfer buffer 126, in block 402.

Once attempts have been made to transfer the data blocks of the entire scalable persistent memory region 128 to backup storage resource 104, the transfer process continues as shown in FIG. 4B, as represented by blocks 412 in FIG. 4A and 414 in FIG. 4B. To handle the rejected data units in such a manner as to maximize subsequent data recovery, operation of processor 108 preferably proceeds under control of system ROM 114, as represented by block 416, again so that the system ROM memory error handler can be utilized to handle ECC errors without causing system crashes.

Processor 108 obtains an identification of a rejected memory unit (e.g., a data block) from the log maintained with reference to block 408 in FIG. 4A. processor 108 then begins a scan operation by reading an increment of data, such as a data line, from the rejected memory unit, as represented by block 420. The system ROM 114 memory error handler then determines, at decision block 422, whether reading the increment led to an ECC error. If so, CPU “scrubs” the offending increment, by replacing or overwriting its contents with error free data such as NULL data, as represented by block 424. Next, in block 426, system ROM ECC memory error handler can clear the ECC flag, and the scrubbed data increment can be written to known good region 130.

On the other hand if no ECC error is encountered at decision block 422, the non-offending data increment is written to known good region 130, in block 428. Next, in decision block 430, it is determined whether the entire rejected data unit has been scanned and, to only the extent necessary, scrubbed. If it has not, a next increment is read, at block 420, and the scan process is repeated. If the entire rejected data unit has been read and transferred to known good region 130, at block 432 the contents of known good region are transferred to backup storage resource 104. As noted above, this transfer is not likely to be rejected by backup storage resource 104, since the error causing increments of the previously rejected data units have been scrubbed and stored in known good region 130.

Next, a determination is made whether all rejected data units have been read and scrubbed, in decision block 434. If not, the identification of the next rejected data unit is obtained at block 418 and the scanning process on it is commenced. Once all rejected data units have been scanned and scrubbed, normal processing can resume, as shown at block 436.

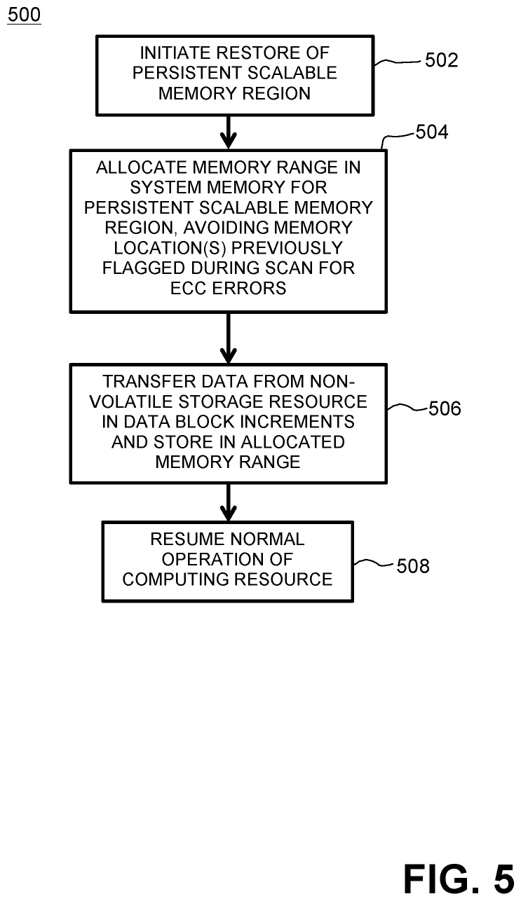

Turning to FIG. 5, there is shown a flow diagram 500 illustrating a data recovery process for a scalable persistent memory region in accordance with one example. The data recovery process of FIG. 5 is may be commenced at block 502 for example upon a system restart, following a system shut down for which a backup of scalable persistent memory region 128 was performed to backup storage resource 104 as described with reference to FIGS. 4A and 4B.

The recover process begins in block 504 with an identification of a memory range in system memory 110 to be designated as a scalable persistent memory region 128. This memory range (contiguous or otherwise), may be the same as prior to the system shutdown necessitating the backup and restore. On the other hand, because scalable persistent memory region is essentially a virtual resource, the allocation of memory to be used for the persistent memory storage region need not be fixed. As a consequence of this, it may be desirable to allocate the memory in system memory 110 for scalable persistent memory region 128 by taking into account any memory locations that have been previously flagged by ECC circuitry as exhibiting ECC errors. For example. Such information is obtained during a scanning operation such as described above with reference to FIG. 3, during which in block 308, ECC-offending memory locations are flagged.

In block 506, the recovery process continues with the transfer of data units (e.g., data blocks) from backup storage resource 104 into the scalable persistent memory region 128 allocated in block 504. Thereafter, normal operation can continue, as represented by block 508. Advantageously, with the processing as described with reference to FIGS. 3, 4A and 4B, and 5, the backup and restore function results in maximization of restored data by avoiding rejection of entire data units (e.g., data blocks) and potential loss of smaller increment(s) due to ECC errors encountered during the backup process.

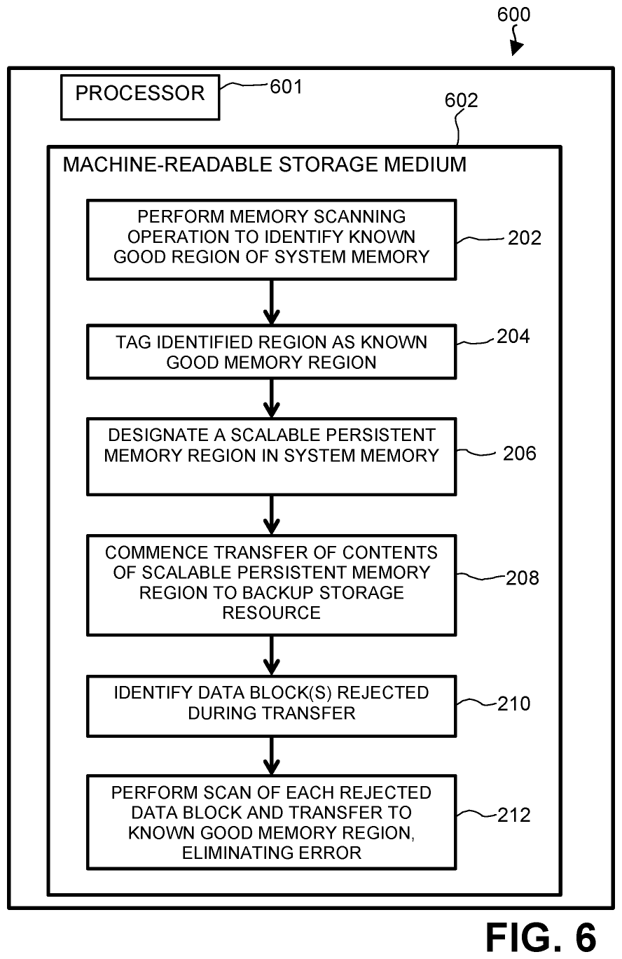

FIG. 6 is a block diagram representing a computing resource 600 implementing a scalable persistent memory, according to one or more disclosed examples. Computing device 600 includes at least one hardware processor 601 and a machine readable storage medium 602. As illustrated, machine readable medium 602 may store instructions, that when executed by hardware processor 601 (either directly or via emulation/virtualization), cause hardware processor 601 to perform one or more disclosed methods relating to establishing and operating a scalable persistent memory region in the system memory of a computing resource. In this example, the instructions stored reflect a methodology as described with reference to flow diagram 200 in FIG. 2. Processor 601 may be, for example, processor 108 in FIG. 1, and machine readable storage medium 602 may be, for example, system ROM 114 or mass data storage 112.

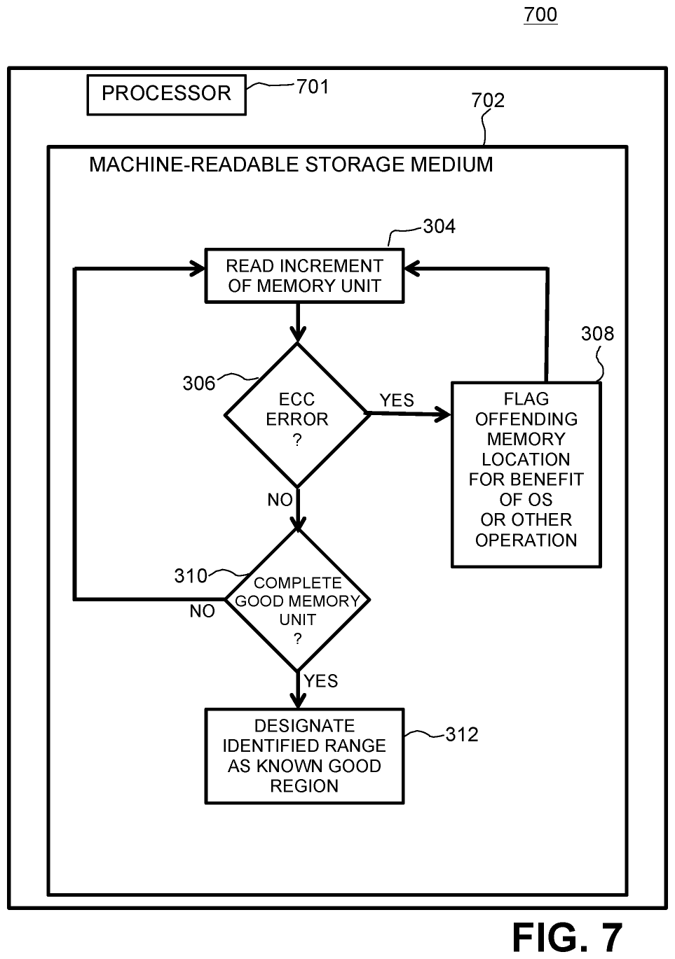

FIG. 7 is a block diagram representing a computing resource 700 implementing a scalable persistent memory according to one or more disclosed examples. Computing device 700 includes at least one processor 701 and a machine readable storage medium 702. As illustrated, machine readable medium 702 may store instructions, that when executed by processor 701 (either directly or via emulation/virtualization), cause processor 701 to perform one or more disclosed methods relating to establishing and operating a scalable persistent memory region in the system memory of a computing resource. In this example, the instructions stored reflect a methodology as described with reference to flow diagram 300 in FIG. 3. Processor 701 may be, for example, processor 108 in FIG. 1, and machine readable storage medium 702 may be, for example, system ROM 114 or mass data storage 112.

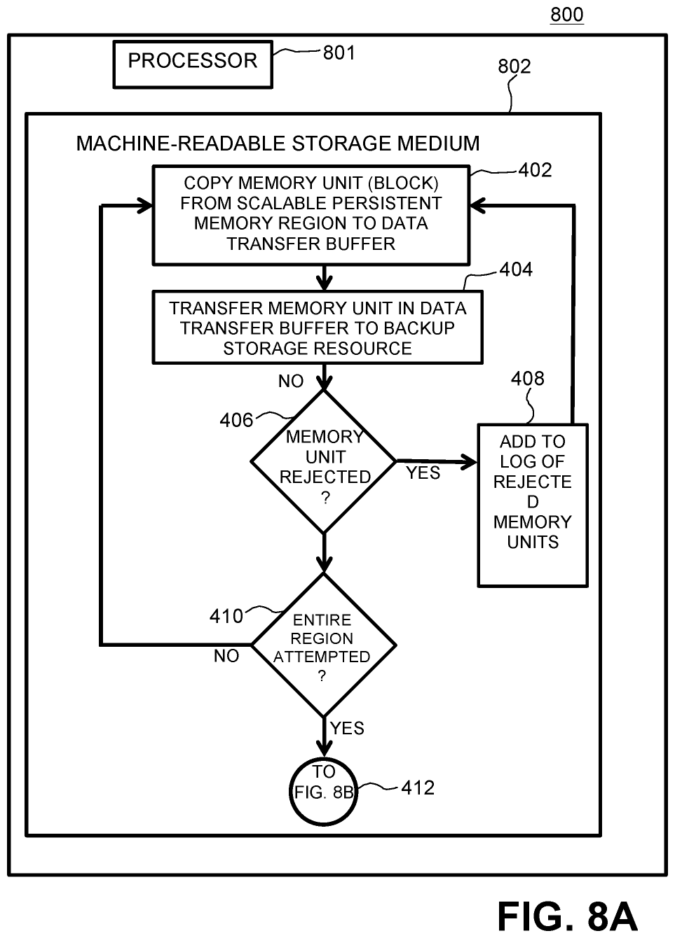

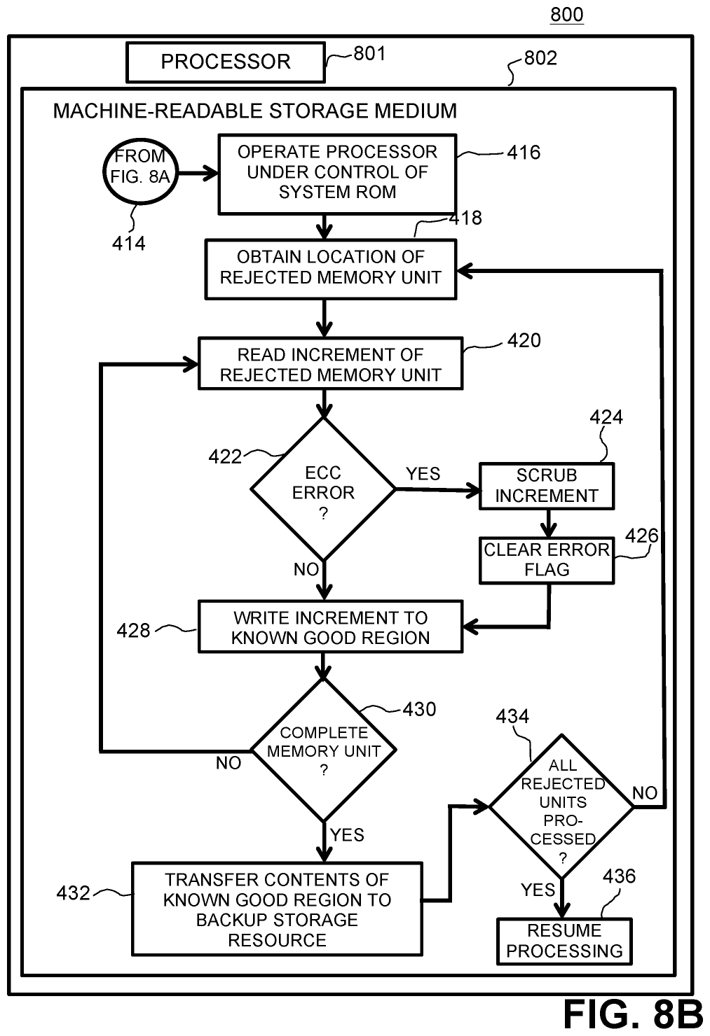

FIGS. 8A and 8B together form a block diagram representing a computing resource 800 implementing a scalable persistent memory according to one or more disclosed examples. Computing device 800 includes at least one processor 801 and a machine readable storage medium 802. As illustrated, machine readable medium 802 may store instructions, that when executed by processor 801 (either directly or via emulation/virtualization), cause processor 801 to perform one or more disclosed methods relating to establishing and operating a scalable persistent memory region in the system memory of a computing resource. In this example, the instructions stored reflect a methodology as described with reference to flow diagram 400 in FIGS. 4A and 4B. Processor 801 may be, for example, processor 108 in FIG. 1, and machine readable storage medium 802 may be, for example, system ROM 114 or mass data storage 112.

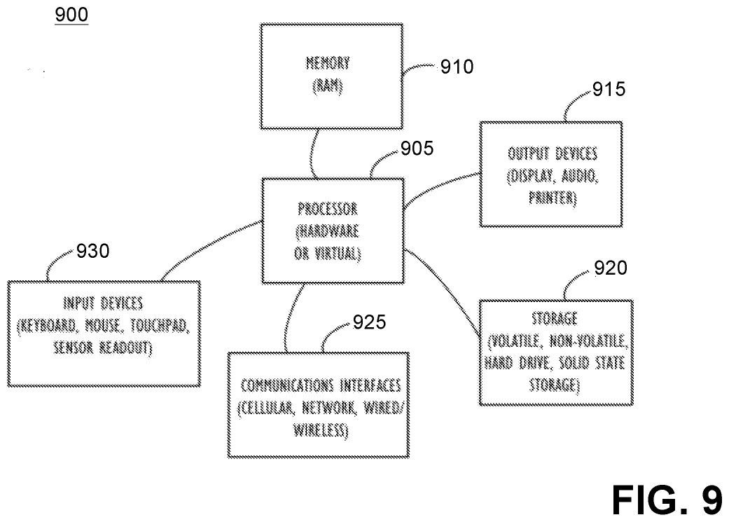

FIG. 9 illustrates a computing resource 900 that may be used to implement or be used with the functions, modules, processing platforms, execution platforms, communication devices, and other methods and processes of this disclosure. For example, computing resource 900 illustrated in FIG. 9 could represent a client device or a physical server device and include either physical hardware or virtual processor(s) depending on the level of abstraction of the computing device. In some instances (without abstraction), computing resource 900 and its elements, as shown in FIG. 9, each relate to physical hardware. Alternatively, in some instances one, more, or all of the elements could be implemented using emulators or virtual machines as levels of abstraction. In any case, no matter how many levels of abstraction away from the physical hardware, computing resource 900 at its lowest level may be implemented on physical hardware.

As also shown in FIG. 9, computing resource 900 may include one or more input devices 930, such as a keyboard, mouse, touchpad, or sensor readout (e.g., biometric scanner) and one or more output devices 915, such as displays, speakers for audio, or printers. Some devices may be configured as input/output devices also (e.g., a network interface or touchscreen display).

Computing resource 900 may also include communications interfaces 925, such as a network communication unit that could include a wired communication component and/or a wireless communications component, which may be communicatively coupled to processor 905. The network communication unit may utilize any of a variety of proprietary or standardized network protocols, such as Ethernet, TCP/IP, to name a few of many protocols, to effect communications between devices. Network communication units may also comprise one or more transceiver(s) that utilize the Ethernet, power line communication (PLC), WiFi, cellular, and/or other communication methods.

As illustrated in FIG. 9, computing resource 900 includes a processing element such as processor 905 that contains one or more hardware processors, where each hardware processor may have a single or multiple processor cores. In one implementation, the processor 905 may include at least one shared cache that stores data (e.g., computing instructions) that are utilized by one or more other components of processor 905. For example, the shared cache may be a locally cached data stored in a memory for faster access by components of the processing elements that make up processor 905. In one or more implementations, the shared cache may include one or more mid-level caches, such as level 2 (L2), level 3 (L3), level 4 (L4), or other levels of cache, a last level cache (LLC), or combinations thereof. Examples of processors include but are not limited to a central processing unit (CPU) or a microprocessor. Although not illustrated in FIG. 9, the processing elements that make up processor 805 may also include one or more of other types of hardware processing components, such as graphics processing units (GPU), application specific integrated circuits (ASICs), field-programmable gate arrays (FPGAs), and/or digital signal processors (DSPs).

FIG. 9 illustrates that memory 910 may be operatively and communicatively coupled to processor 905. Memory 910 may be a non-transitory medium configured to store various types of data. For example, memory 910 may include one or more storage devices 920 that comprise a non-volatile storage device and/or volatile memory. Volatile memory, such as random-access memory (RAM), can be any suitable non-permanent storage device. The non-volatile storage devices 920 can include one or more disk drives, optical drives, solid-state drives (SSDs), tap drives, flash memory, read only memory (ROM), and/or any other type of memory designed to maintain data for a duration of time after a power loss or shut down operation. In certain instances, the non-volatile storage devices 920 may be used to store overflow data if allocated RAM is not large enough to hold the working data. The non-volatile storage devices 920 may also be used to store programs that are loaded into the RAM when such programs are selected for execution.

Persons of ordinary skill in the art are aware that software programs may be developed, encoded, and compiled in a variety of computing languages for a variety of software platforms and/or operating systems and subsequently loaded and executed by processor 905. In one implementation, the compiling process of the software program may transform program code written in a programming language to another computer language such that the processor 905 is able to execute the programming code. For example, the compiling process of the software program may generate an executable program that provides encoded instructions (e.g., machine code instructions) for processor 905 to accomplish specific, non-generic, particular computing functions.

After the compiling process, the encoded instructions may then be loaded as computer executable instructions or process steps to processor 905 from storage device 920, from memory 910, and/or embedded within processor 905 (e.g., via a cache or on-board ROM). Processor 905 may be configured to execute the stored instructions or process steps in order to perform instructions or process steps to transform the computing device into a non-generic, particular, specially programmed machine or apparatus. Stored data, e.g., data stored by a storage device 920, may be accessed by processor 905 during the execution of computer executable instructions or process steps to instruct one or more components within the computing resource 900.

A user interface (e.g., output devices 915 and input devices 930) can include a display, positional input device (such as a mouse, touchpad, touchscreen, or the like), keyboard, or other forms of user input and output devices. The user interface components may be communicatively coupled to processor 905. When the output device is or includes a display, the display can be implemented in various ways, including by a liquid crystal display (LCD) or a cathode-ray tube (CRT) or light emitting diode (LED) display, such as an organic light emitting diode (OLED) display. Persons of ordinary skill in the art are aware that the computing resource 900 may comprise other components well known in the art, such as sensors, powers sources, and/or analog-to-digital converters, not explicitly shown in FIG. 9.

Certain terms have been used throughout this description and claims to refer to particular system components. As one skilled in the art will appreciate, different parties may refer to a component by different names. This document does not intend to distinguish between components that differ in name but not function. In this disclosure and claims, the terms “including” and “comprising” are used in an open-ended fashion, and thus should be interpreted to mean “including, but not limited to . . . .” Also, the term “couple” or “couples” is intended to mean either an indirect or direct wired or wireless connection. Thus, if a first device couples to a second device, that connection may be through a direct connection or through an indirect connection via other devices and connections. The recitation “based on” is intended to mean “based at least in part on.” Therefore, if X is based on Y, X may be a function of Y and any number of other factors.

The above discussion is meant to be illustrative of the principles and various implementations of the present disclosure. Numerous variations and modifications will become apparent to those skilled in the art once the above disclosure is fully appreciated. It is intended that the following claims be interpreted to embrace all such variations and modifications.

What is claimed is:

1. A scalable persistent memory, comprising:
a memory controller implementing an error correction protocol, coupled to a system memory and operable with a processor to allocate a scalable persistent memory region, comprising at least one data block consisting of a plurality of data lines, within said system memory;
a backup storage resource, in data communication with said system memory, for storing said at least one data block of said scalable persistent memory region, said backup storage resource being operable to reject storage of a data block determined by said error correction protocol to contain a data error;
wherein said processor is responsive to rejection of a data block by said backup storage resource to:
scan said rejected data block in data line increments;
overwrite any data line of the rejected data block found to contain data errors with error-free data;
store said scanned data block including said overwritten data line in a known good storage region of said system memory, said known good storage region being previously determined to be error-free; and
transfer contents of said known good storage region to said backup storage resource.

2. The scalable persistent memory of claim 1, further comprising system read-only memory (“system ROM”) coupled to said processor for providing instructions for controlling operation of said processor during said scan of said rejected data block.

3. The scalable persistent memory of claim 1, wherein said backup storage resource comprises non-volatile storage.

4. The scalable persistent memory of claim 3, wherein said backup storage resource comprises a non-volatile dual in-line memory module.

5. The scalable persistent memory of claim 2, wherein said known good region of said system memory is identified by said processor performing a scan of locations in said system memory under control of said system ROM.

6. The scalable persistent memory of claim 1, wherein said system memory comprises dynamic random-access memory.

7. The scalable persistent memory of claim 1, wherein said data blocks comprise 128 kB of data consisting of 64 byte data lines.

8. A method of implementing a scalable persistent memory, comprising:
allocating a scalable persistent memory region, the scalable persistent memory region comprising a plurality of data blocks, each data block consisting of a plurality of data lines, within a system memory of a computing resource;
attempting to transfer each data block of said scalable persistent memory region to a backup storage resource, said backup storage resource being operable to reject storage of any data block determined by an error correction protocol to contain a data error;
wherein a processor is responsive to a rejection of a data block by said backup storage resource, to:
scan said rejected data block in data line increments and overwrite any data line found to contain data errors with error-free data;
store said scanned data block with the error-free data in a known good storage region of said system memory, said known good storage region being previously determined by said processor to be error-free; and
transfer contents of said known good storage region to said backup storage resource.

9. The method of claim 8, further comprising:
prior to said attempting to transfer each data block of said scalable persistent memory region to said backup storage resource, controlling said processor to scan data lines in said system memory to allocate said known good region of system memory consisting of only data lines which are error free.

10. The method of claim 8, wherein said attempting to transfer each data block of said scalable persistent memory region to said backup storage device is initiated in response to a system shutdown.

11. The method of claim 10, where said system shutdown is a planned system shutdown.

12. The method of claim 8, wherein said known good storage region comprises a region of at least one data block in storage capacity.

13. The method of claim 12, wherein each data block comprises 128 kB of data and each data line comprises 64 bytes of data.

14. The method of claim 9, wherein said scanning of data lines in said system memory to allocate said known good region further comprises flagging locations of said system memory found to contain data errors such that such locations can be avoided during subsequent computing operations.

15. A non-transitory computer-readable medium comprising computer-executable instructions stored thereon that when executed by at least one processor causes the at least one processor to:
allocate a scalable persistent memory region, comprising a plurality of data blocks each consisting of a plurality of data lines, within a system memory of a computing resource;
attempt to transfer each data block of said scalable persistent memory region to a backup storage resource, said backup storage resource being adapted to reject storage of any data block determined by an error correction protocol to contain a data error;
scan said rejected data block in data line increments and overwrite any data line found to contain data errors with error-free data;
store said scanned data block in a known good storage region of said system memory, said known good storage region being previously determined to be error-free; and
transfer contents of said known good storage region to said backup storage resource.

16. The non-transitory computer-readable medium of claim 15, wherein said computer-executable instructions further cause the at least one processor, prior to attempting to transfer each data block of said scalable persistent memory region to said backup storage resource, to:
scan data lines in said system memory to allocate said known good region of system memory consisting of only data lines which are error free.

17. The non-transitory computer-readable medium of claim 15, wherein said computer-executable instructions further cause the at least one processor to flag locations of said system memory found, during said scan to allocate said known good region, to contain data errors, such that such locations can be avoided during subsequent computing operations.

18. The non-transitory computer-readable medium of claim 15, wherein said computer-executable instructions further cause the at least one processor to be responsive to a system shutdown to initiate said attempt to transfer each data block of said scalable persistent memory region to said backup storage resource.

19. The non-transitory computer-readable medium of claim 15, wherein said non-transitory computer readable medium comprises system read-only memory (“system ROM’) coupled to said processor.

20. The non-transitory computer-readable medium of claim 19, wherein said system ROM includes a memory error handler.
